(19) United States
(12) Patent Application Publication
(10) Pub. No.: US 2010/0068509 A1
(43) Pub. Date: Mar. 18, 2010

(54) MEDIA HAVING IMPROVED SURFACE SMOOTHNESS AND METHODS FOR MAKING THE SAME

(75) Inventors: Qing Ma, San Jose, CA (US); Nathan Franklin, San Mateo, CA (US); Li-Peng Wang, San Jose, CA (US); Robert Chen, San Francisco, CA (US)

Correspondence Address: FLIESLER MEYER LLP, 650 CALIFORNIA STREET, 14TH FLOOR, SAN FRANCISCO, CA, 94108, US

(73) Assignee: NANOCHIP, INC., Fremont, CA (US)

(21) Appl. No.: 12/258,220

(22) Filed: Oct. 24, 2008

Related U.S. Application Data
(60) Provisional application No. 61/097,811, filed on Sep. 17, 2008.

(51) Int. Cl. B32B 9/00; C23C 14/34; C23C 16/40; B05D 3/10; B32B 5/00; B05D 3/02

(52) U.S. Cl. 428/336; 427/419.3; 204/192.15; 427/255.19; 427/376.2; 428/701; 427/336

(57) ABSTRACT

Provided herein are media for storing information and methods of forming such media. A strontium ruthenate (SRO) layer is provided. In certain embodiments, a titanium terminated (Ti-terminated) surface is formed on the SRO layer, and a lead zirconate titanate (PZT) layer is formed on the Ti-terminated surface. In other embodiments, a Ti-terminated surface is formed on the SRO layer, a lead titanate (PTO) layer is formed on the Ti-terminated surface, and a PZT layer is formed on the PTO layer. Preferably, the PZT layer is grown on the Ti-terminated surface, or the PTO layer, by step-flow or layer-by-layer growth, so that the resulting media has an atomically smooth surface.

### PRIORITY CLAIM

The present application claims priority under 35 U.S.C. §119(e) to U.S. Provisional Patent Application No. 61/097,811, filed Sep. 17, 2008 (Attorney Docket No. NANO-01121US0), which is incorporated herein by reference.

### BACKGROUND

Software developers continue to develop steadily more data intensive products, such as ever-more sophisticated, and graphic intensive applications and operating systems. As a result, higher capacity memory, both volatile and non-volatile, has been in persistent demand. Added to this demand is the need for capacity for storing data and media files, and the confluence of personal computing and consumer electronics in the form of portable media players (PMPs), personal digital assistants (PDAs), sophisticated mobile phones, and laptop computers, all of which place a premium on compactness and reliability.

Nearly every personal computer and server in use today contains one or more hard disk drives (HDD) for permanently storing frequently accessed data. Every mainframe and supercomputer is connected to hundreds of HDDs. Consumer electronic goods ranging from camcorders to digital data recorders use HDDs. While HDDs store large amounts of data, HDDs consume a great deal of power, require long access times, and require “spin-up” time on power-up. Further, HDD technology based on magnetic recording technology is approaching a physical limitation due to super paramagnetic phenomenon. Data storage devices based on scanning probe microscopy (SPM) techniques have been studied as future ultra-high density (>1Tbit/in2) systems. There is a need for techniques and structures to read and write to a ferroelectric media that facilitate desirable data bit transfer rates and areal densities.

### BRIEF DESCRIPTION OF THE DRAWINGS

Details of the present invention are explained with the help of the attached drawings in which:

FIG. 1A is a perspective representation of a crystal of a ferroelectric material having a polarization.

FIG. 1B is a side representation of the crystal of FIG. 1A.

FIG. 2A is a cross-sectional side view of an information storage device including a plurality of tips extending from corresponding cantilevers toward a media.

FIG. 2B is a side view of a tip of the system of FIG. 2A arranged over a domain of a ferroelectric recording layer.

FIG. 3A illustrates various stages for forming a media in accordance with embodiments of the present invention.

FIG. 3B is a high level flow diagram that is used to summarize methods for forming the media of FIG. 3A in accordance with embodiments of the present invention.

FIG. 4 is a simplified schematic side view of media according to an embodiment of the present invention.

FIG. 5 schematically illustrates two stages for forming a media in accordance with further embodiments of the present invention.

FIG. 6A illustrates various stages for forming a media in accordance with alternative embodiments of the present invention.

FIG. 6B is a high level flow diagram that is used to summarize methods for forming the media of FIG. 6A in accordance with embodiments of the present invention.

### DETAILED DESCRIPTION

Common reference numerals are used throughout the drawings and detailed description to indicate like elements; therefore, reference numerals used in a drawing may or may not be referenced in the detailed description specific to such drawing if the associated element is described elsewhere.

Ferroelectrics are members of a group of dielectrics that exhibit spontaneous polarization—i.e., polarization in the absence of an electric field. Permanent electric dipoles can exist in ferroelectric materials. Common ferroelectric materials include lead zirconate titanate (Pb[ZrₓTi₁₋ₓ]O₃ 0<x<1, also referred to herein as PZT). Taken as an example, PZT is a ceramic perovskite material that has a spontaneous polarization which can be reversed in the presence of an electric field.

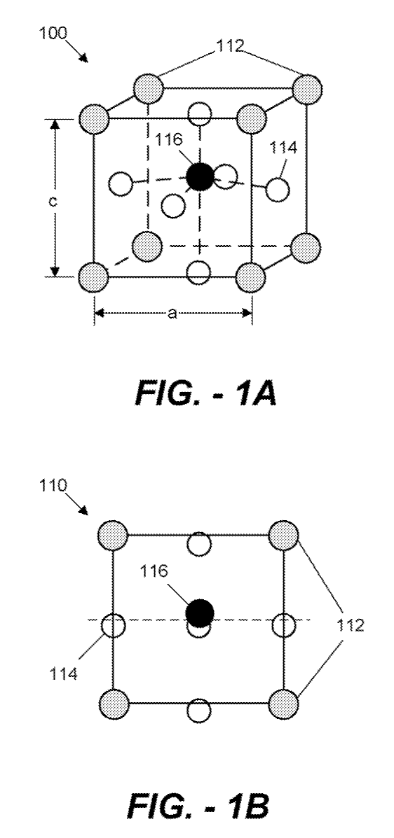

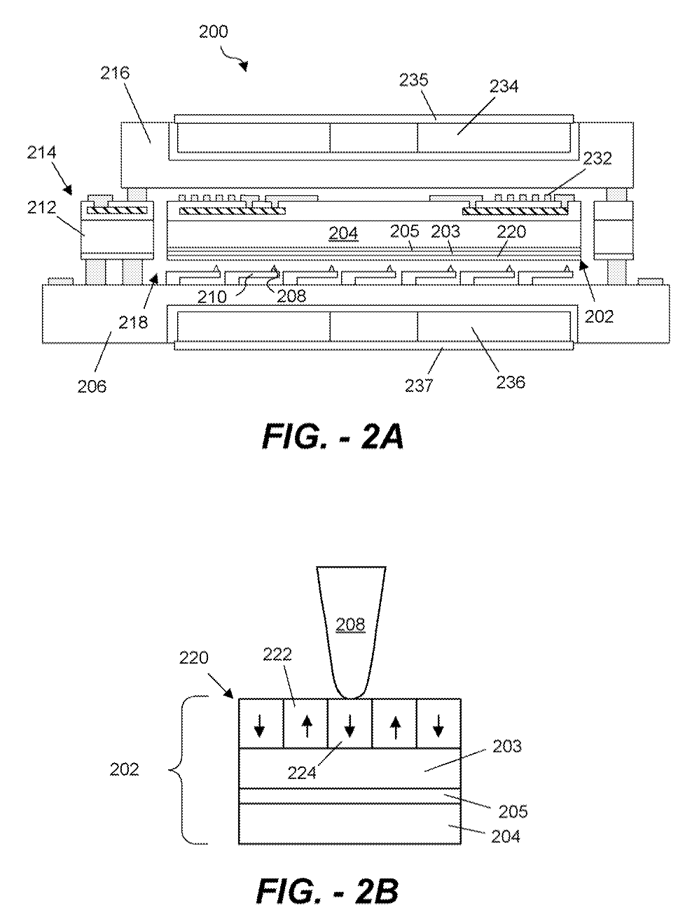

Referring to FIGS. 1A and 1B, a crystal of PZT is shown. Spontaneous polarization is a consequence of the positioning of the Pb²⁺, Zr⁴⁺/Ti⁴⁺, and 0²⁻ ions within the unit cell 110. The Pb²⁺ ions 112 are located at the corners of the unit cell 110, which is of tetragonal symmetry (a cube that has been elongated slightly in one direction). A permanent ionic dipole moment results from the relative displacements of the 0²⁻ ions 114 and the Zr⁴⁺/Ti⁴⁺ ion 116 from their symmetrical positions. The crystal shown has a dipole moment resulting from 0²⁻ ions 114 located near, but slightly below, the centers of each of the six faces, and a Ti⁴⁺ (or Zr⁴⁺) ion 116 displaced upward from the center of the unit cell 110.

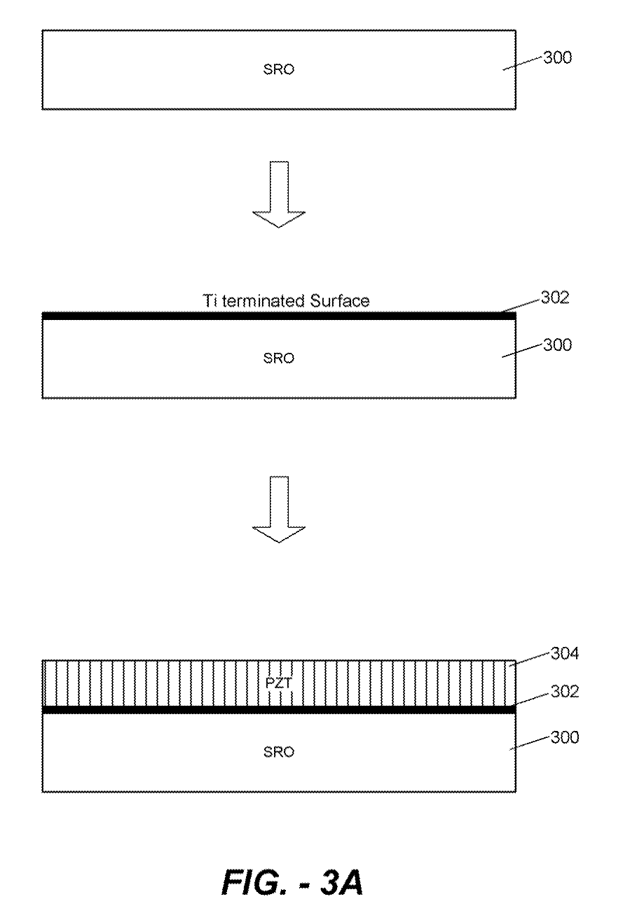

Ferroelectric films have been proposed as promising recording media, with a bit state corresponding to a spontaneous polarization direction of the media, wherein the spontaneous polarization direction is controllable by way of application of an electric field. FIG. 2A is a simplified cross-sectional diagram of an exemplary system for storing information 200 (also referred to herein as a memory device) with which embodiments of media and methods of forming media in accordance with the present invention can be used. Memory devices enabling potentially higher density storage relative to current ferromagnetic and solid state storage technology can include nanometer-scale heads such as contact probe tips, non-contact probe tips, and the like capable of one or both of reading and writing to a media. Memory devices for high density storage can include seek-and-scan probe (SSP) memory devices comprising cantilevers from which probe tips extend for communicating with a media. The cantilevers and probe tips can be implemented in a micro-electromechanical systems (MEMS) device with a plurality of read-write channels working in parallel. Probe tips are hereinafter referred to as tips and can comprise structures that communicate with a media in one or more of contact, near contact, and non-contact mode. A tip need not be a protruding structure. For example, in some embodiments, a tip can comprise a cantilever or a portion of the cantilever.

The memory device 200 comprises a tip substrate 206 arranged substantially parallel to a media 202. Cantilevers 210 extend from the tip substrate 206, and tips 208 extend from respective cantilevers 210 toward the surface of the media 202. A media (also referred to herein as a media stack) can comprise one or more layers of patterned and/or unpatterned ferroelectric films. A ferroelectric recording layer 220 of the media can achieve ultra high bit recording density because the thickness of a 180° domain wall in ferroelectric material is in the range of a few lattices (1-2 nm). The media 202 is associated with a media platform 204 (e.g., a silicon substrate 204). A media substrate 214 comprises the media platform 204 suspended within a frame 212 by a plurality of suspension structures (e.g., flexures, not shown). The media platform 204 can be urged within the frame 212 by way of thermal actuators, piezoelectric actuators, voice coil motors, etc. As shown, the media platform 204 can be urged by electromagnetic motors comprising electrical traces 232 (also referred to herein as coils, although the electrical traces need not contain turns or loops) formed on the media platform and placed in a magnetic field so that controlled movement of the media platform 204 can be achieved when current is applied to the electrical traces 232. A magnetic field is generated outside of the media platform 204 by a first permanent magnet 234 and second permanent magnet 236 arranged so that the permanent magnets 234,236 roughly map the range of movement of the coils 232. The permanent magnets 234,236 can be fixedly connected with a rigid or semi-rigid structure such as a flux plate 235,237 formed from steel, or some other material for acting as a magnetic flux return path and containing magnetic flux. The media substrate 214 can be bonded with the tip substrate 206 and a cap 216 can be bonded with the media substrate 214 to seal the media platform 204 within a cavity 218. Optionally, nitrogen or some other passivation gas can be introduced and sealed in the cavity 218. In alternative embodiments, memory devices can be employed wherein a tip platform is urged relative to the media, or alternative wherein both the tip platform and media can be urged.

FIG. 2B is a partial cross-section showing a distal end of a tip 208 in contact or near contact with the media 202. The tip 208 can perform one or both of reading and writing. The media 202 comprises a ferroelectric recording layer 220 including domains having spontaneous polarization in an “UP” direction 222 and a “DOWN” direction 224. The ferroelectric recording layer 220 can comprise one or more layers of ferroelectric material. The media 202 further comprises a conductive layer 203 above which the recording layer 220 is formed so that the recording layer 220 is disposed between the tip 208 and the conductive layer 203, and typically a substrate 204 (or base layer 205, as shown) over which the conductive layer 203 is formed.

As a write tip, the tip is a conductive electrode that can apply a potential across the recording layer to selectably set—either “UP” or “DOWN”—the spontaneous polarization of a domain. As a read tip, multiple different techniques can be applied to determine the polarization of a domain. In an embodiment, a tip acts as an antenna, with charge coupling to the tip to induce a voltage that varies with polarization at a frequency determined by relative movement between the media and the tip. This readout technique is referred to herein as a radio frequency (RF) charge technique, and is described in detail in U.S. patent application Ser. No. 11/688,806 entitled “Systems and Methods of Writing and Reading a Ferro-electric Media with a Probe Tip,” filed Mar. 20, 2007, which is incorporated herein by reference. In an alternative embodiment, a potential can be applied at a radio frequency (RF) across the recording layer below a switching level to induce expansion or contraction in the ferroelectric layer which in turn causes vibration of the tip. Tip vibration causes detectable variation in a capacitance of the cantilever. This readout technique is referred to hereinafter as piezoelectric force modulated charge (“PFMC”) sensing technique, and is described in detail in U.S. patent application Ser. No. 12/030,101 entitled “Method and Device for Detecting Ferroelectric Polarization,” filed Feb. 12, 2008, which is incorporated herein by reference.

It is desirable for the top surface of the media 202 to be as smooth as possible, because surface roughness degrades read/write performance and induces tip wear. When ferroelectric films (e.g., PZT) are epitaxially grown a single crystalline bottom electrode (e.g., SRO), the growth is usually be island-coalescence mechanism. However, growth by island-coalescence mechanism produces relatively rough surfaces with pin-holes, especially when films are thin (<25 nm). Methods for forming media, in accordance with embodiments of the present invention described below, can be used to produce smooth media surfaces. In certain embodiments, the interface energy between the ferroelectric film and the bottom electrode is reduced so that step flow or layer-by-layer growth of the ferroelectric film is achieved, to preferably produce atomically smooth surfaces. In specific embodiments, described in more detail below, this is accomplished by promoting wetting at the interface between the ferroelectric film and the bottom electrode. In an atomically smooth surface, steps are single lattice units, where a lattice step can be, e.g., 0.4 nm. Additionally, in an atomically smooth surface, these lattice steps are at a very low density, e.g., less than 1 per 100 nm. Atomic smoothness also implies that these steps form because the surface they are growing on has some type of topography, but the grown layer does not add to the topography. Even single crystal silicon has lattice steps on it, and their density depends on how perfectly cut or polished the wafer is. But in general, the roughness of an atomically smooth surface is less than 0.2 nm.

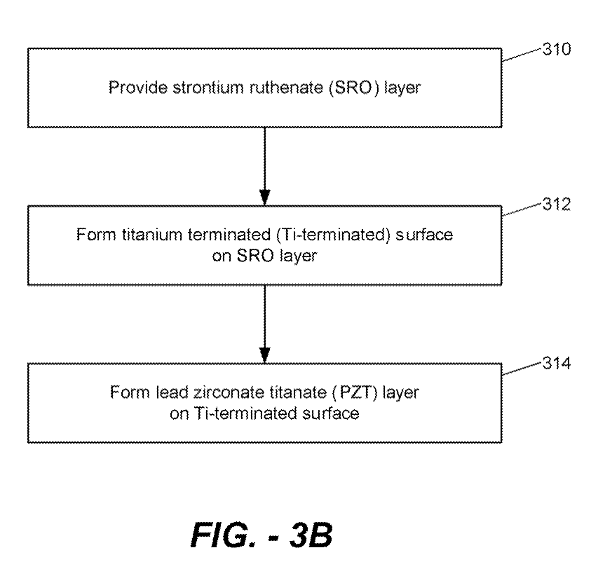

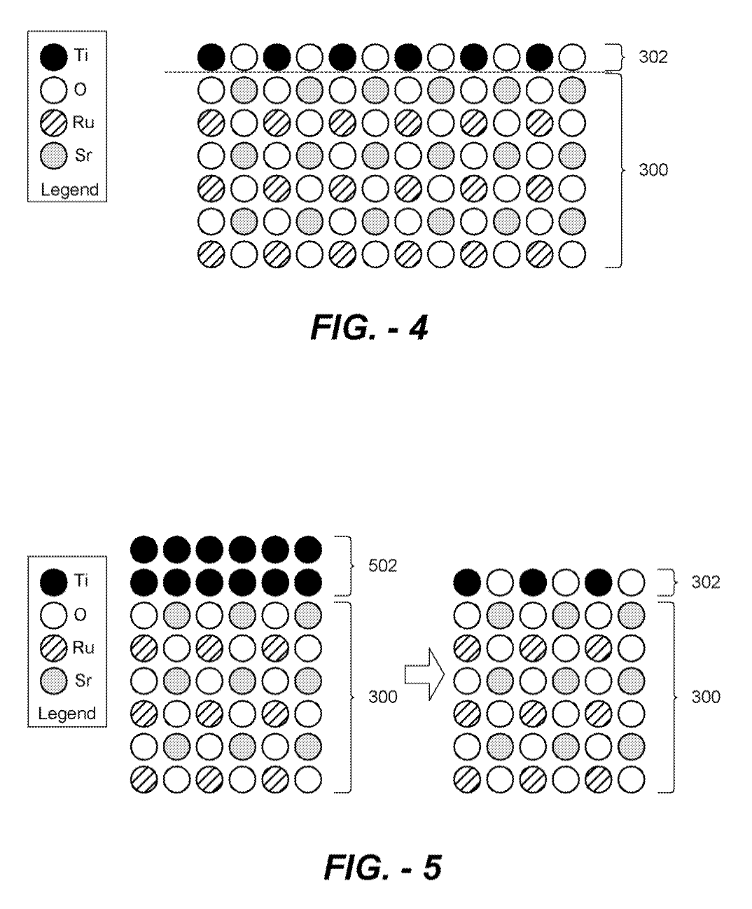

Reference will now be made to FIGS. 3A and 3B. FIG. 3A illustrates various stages for forming a media in accordance with embodiments of the present invention. FIG. 3B is a high level flow diagram that is used to summarize methods for forming the media of FIG. 3A in accordance with embodiments of the present invention. As shown at the top panel in FIG. 3A (and at step 310 in FIG. 3B), a strontium ruthenate layer (SrRuO₃, also referred to herein as SRO) 300 is provided. SRO is a well functioning member of a family of metallic conducting oxides with a perovskite type structure, making SRO a suitable material for use as a conductive layer (e.g., as conductive layer 203 in FIG. 2). The conductive SRO layer 300 can be formed on a substrate (e.g., substrate 204 in FIG. 2), and in an embodiment the SRO layer 300 can have a thickness ranging from 50 to 100 nm.

The SRO layer 300 can be acceptably formed by using one or more thin film techniques such as pulsed laser deposition (PLD), metal oxide chemical vapor deposition (MOCVD), molecular beam epitaxy (MBE) and sputtering. A substrate (e.g., 204 in FIG. 2) facilitates crystalline growth of the conductive SRO layer 300. Strontium titanate (SrTiO₃, also referred to herein as STO) is a high-K dielectric having a perovskite type structure with acceptable lattice matching to SRO. Accordingly, STO is suitable as a substrate. However, bulk STO may have an undesirably small surface area on which to form SRO (e.g., typically about 3 cm×10 cm). Further, bulk STO may be undesirably difficult to functionally integrate in a system having a structure as shown in FIG. 2. In an embodiment, STO can be formed as a base layer (e.g., 205 in FIG. 2) on a silicon substrate. For example, STO can be epitaxially grown on a silicon wafer enabling fabrication of the media using processes associated with very-large-scale integration (VLSI) technology. STO can be grown using one or more known techniques such as PLD, MOCVD, MBE and sputtering.

As shown at the middle panel in FIG. 3A (and at step 312 in FIG. 3B), a titanium terminated (Ti-terminated) surface 302 is formed on the SRO layer 203. Thereafter, as shown at the bottom panel in FIG. 3A (and at step 314 in FIG. 3B), a lead zirconate titanate (PZT) layer 304 (which provides the ferroelectric recording layer 220 in FIG. 2) is formed on the Ti-terminated surface 302. In such embodiments, the Ti-terminated surface 302 is used because it is believed that the Ti-terminated surface 302 wets the SRO layer 300, such that PZT growth thereon is by step-flow or layer-by-layer epitaxial growth (as opposed to island-coalescence epitaxial growth), thereby improving the smoothness of the resulting media. Stated another way, it is believed that the Ti-terminated surface 302 reduces the interface energy between the SRO layer 300 and the PZT layer 304, so that step-flow or layer-by-layer epitaxial growth of the PZT layer 304 can be achieved.

There are various ways in which the Ti-terminated surface 302 can be formed on the SRO layer 300 at step 312. In accordance with an embodiment, the Ti-terminated surface is formed on the SRO layer 300 by epitaxially growing an ultra-thin strontium titanate (STO) layer (preferably between 1 and 10 lattices) on the SRO layer 300, and then treating the STO layer with buffered hydrofluoric acid (BHF) to produce the Ti-terminated surface. In such an embodiment, the STO layer can have a thickness ranging from about 0.4 nm to 4.0 nm, and can be epitaxially grown on the SRO layer 300 using one or more known techniques such as MBE, MOCVD and sputtering.

In an alternative embodiment for forming the Ti-terminated surface 302 on the SRO layer 300 at step 312, the SRO layer 300 is annealed to produce a strontium terminated (Sr-terminated) surface, and an ultra-thin layer of titanium oxide is deposited on the Sr-terminated surface to thereby produce the Ti-terminated surface 302. The titanium oxide can be, e.g., TiO, Ti₂O₃, Ti₃O₅, TiO₂, but is not limited thereto. The annealing of the SRO layer 300, to produce the Sr-terminated surface, can be done at an anneal temperature ranging from 200 to 700 degrees Celsius, for a length of time ranging from 5 seconds to 30 minutes. The annealing can be performed in an ambient environment, but is not limited thereto. Typically, the higher the anneal temperature the less annealing time necessary, and the lower the anneal temperature, the greater the length of annealing time necessary. The ultra-thin layer of titanium oxide, which is provided to change the surface wetting properties of the SRO layer 300, preferably has a thickness of 0.2 to 2.0 monolayers, and can be deposited on the Sr-terminated surface using one or more known techniques such as MBE, atomic layer deposition (ALD) and evaporation. A resulting SRO layer 300 with a Ti-terminated surface 302 is schematically illustrated in FIG. 4.

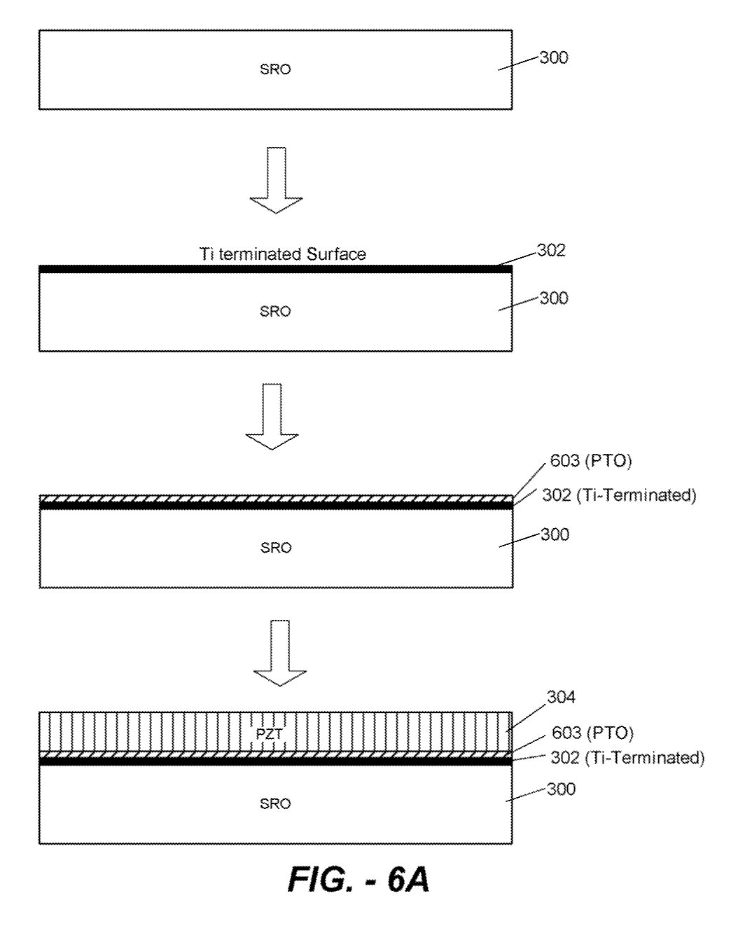

FIG. 5 will now be used to describe a further embodiment for forming the Ti-terminated surface 302 on the SRO layer 300 at step 312. In this embodiment, the SRO layer 300 is annealed to produce a Sr-terminated surface, in a similar manner as was just discussed above. A thin titanium (Ti) layer is then formed on the Sr-terminated surface by one or more known techniques such as sputtering, evaporation, chemical vapor deposition (CVD) and ALD. The panel on the left in FIG. 5 is a schematic illustration of the SRO layer 300 with an Sr-terminated surface, on top of which is a Ti layer 502. A portion of the titanium layer 502 is then dissolved, e.g., using buffered hydrofluoric acid (BHF), to thereby produce the titanium terminated surface 302. The resulting Ti-terminated surface 302 is schematically illustrated in the right panel in FIG. 5. In place of BHF, alternative wet etching solutions that provide a higher etching rate for Ti than for SRO can be used to perform the dissolving of the portion of the Ti layer 502.

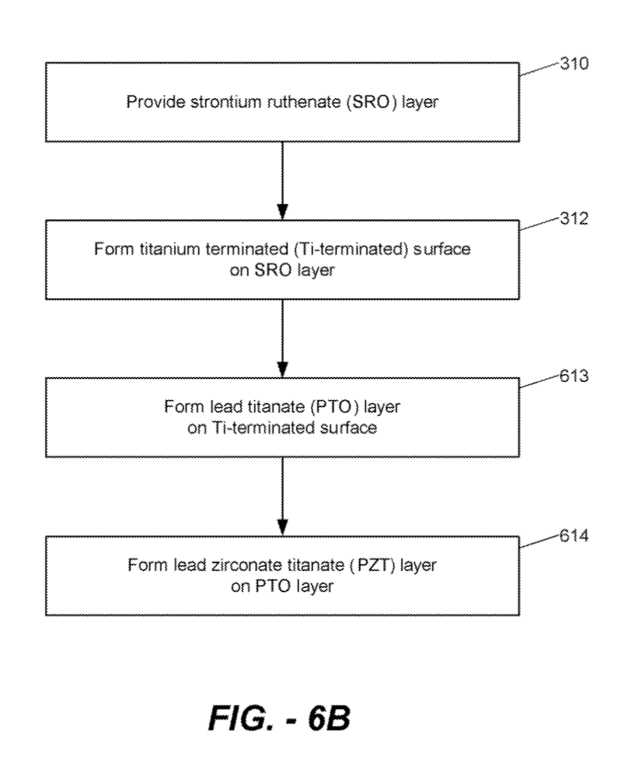

Reference will now be made to FIGS. 6A and 6B. FIG. 6A illustrates various stages for forming a media in accordance with further embodiments of the present invention. FIG. 6B is a high level flow diagram that is used to summarize methods for forming the media of FIG. 6A. As shown at the top panel in FIG. 6A (and at step 310 in FIG. 6B), a SRO layer 300 is provided. Since step 310 in FIG. 6B is the same as step 310 described above with reference to FIG. 3B, this step need not be described in additional detail.

As shown at the second panel in FIG. 6A (and at step 312 in FIG. 6B), a titanium terminated (Ti-terminated) surface 302 is formed on the SRO layer 203. Any of the above mentioned techniques (discussed with reference to FIGS. 3A, 3B, 4 and 5) for forming a Ti-terminated surface 302 on a SRO layer 300 can be used, including those discussed above with reference to step 312 in FIG. 3B.

As shown at the third panel in FIG. 6A (and at step 613 in FIG. 6B), an ultra-thin lead titanate (PbTiO₃, also referred to a PTO) layer 603 is formed on the Ti-terminated surface 302. Thereafter, as shown at the bottom panel in FIG. 6A (and at step 614 in FIG. 6B), a PZT layer 304 (which provides the ferroelectric recording layer 220 in FIG. 2) is formed on the PTO layer 603. The ultra-thin PTO layer 603 (preferably between 1 and 10 lattices), which can be formed by one or more known techniques such as sputtering, MOCVD and MBE, can be considered a buffer layer between the Ti-terminated SRO layer 300,302 and the PZT layer 304. In such embodiments, the Ti-terminated surface 302 and the PTO layer 603 are used because it is believed that PZT growth on such a stack (300,302,603) will be by step-flow or layer-by-layer epitaxial growth (as opposed to island-coalescence epitaxial growth), thereby improving the smoothness of the resulting media. More specifically, it is believed that the Ti-terminated surface 302 reduces the interface energy between the SRO layer 300 and the PTO layer 603, so that step-flow or layer-by-layer epitaxial growth of the PTO layer 603 can be achieved. The resulting smooth PTO layer 603 then allows for step-flow or layer-by-layer epitaxial growth thereon of the PZT layer 304.

Embodiments of the present invention are directed to methods for forming media, as well as the resulting media. Additionally, embodiments of the present invention are also directed to systems/devices for storing information (such as system 200 described with reference to FIG. 3) that include such media.

The foregoing description of embodiments of the present invention have been presented for purposes of illustration and description. It is not intended to be exhaustive or to limit the invention to the precise forms disclosed. Many modifications and variations will be apparent to practitioners skilled in this art. The embodiments were chosen and described in order to best explain the principles of the invention and its practical application, thereby enabling others skilled in the art to understand the invention for various embodiments and with various modifications as are suited to the particular use contemplated. It is intended that the scope of the invention be defined by the following claims and their equivalents.

What is claimed is:

1. A method of forming a media, comprising:
(a) providing a strontium ruthenate layer;
(b) forming a titanium terminated surface on the strontium ruthenate layer; and
(c) forming a lead zirconate titanate layer on the titanium terminated surface.

2. The method of claim 1, wherein step (c) comprises growing the lead zirconate titanate layer on the titanium terminated surface by step-flow or layer-by-layer growth.

3. The method of claim 1, wherein step (b) comprises:
(b.1) epitaxially growing a strontium titanate layer on the strontium ruthenate layer; and
(b.2) treating the strontium titanate layer with buffered hydrofluoric acid to produce the titanium terminated surface.

4. The method of claim 3, wherein the strontium titanate layer grown at step (b.1) has a thickness ranging from about 0.4 nm to 4.0 nm.

5. The method of claim 3, wherein the strontium titanate layer is epitaxially grown on the strontium ruthenate layer using one of the following:
molecular beam epitaxy;
sputtering; or
metal oxide chemical vapor deposition.

6. The method of claim 1, wherein the forming the titanium terminated surface on the strontium ruthenate layer at step (b) comprises:
(b.1) annealing the strontium ruthenate to produce a strontium terminated surface; and
(b.2) depositing titanium oxide on the strontium terminated surface to thereby produce the titanium terminated surface.

7. The method of claim 1, wherein the titanium oxide deposited at step (b.2) has a thickness of about 0.2 to about 2.0 monolayers.

8. The method of claim 6, wherein the annealing at step (b.1) is done at an anneal temperature between about 200 degrees Celsius and about 700 degrees Celsius.

9. The method of claim 8, wherein the annealing at step (b.1) is performed for a length of time between about 5 seconds to 30 minutes.

10. The method of claim 6, wherein step (b.2) comprising depositing titanium oxide on the strontium terminated surface using one of the following:
molecular beam epitaxy;
atomic layer deposition; or
evaporation.

11. The method of claim 1, wherein the forming the titanium terminated surface on the strontium ruthenate layer at step (b) comprises:
(b.1) annealing the strontium ruthenate to produce a strontium terminated surface;
(b.2) forming a titanium layer on the strontium terminated surface; and
(b.3) dissolving a portion of the titanium layer to thereby produce the titanium terminated surface.

12. The method of claim 11, wherein step (b.2) comprising depositing the titanium layer on the strontium terminated surface using one of the following:
sputtering;
evaporation;
chemical vapor deposition; or
atomic layer deposition.

13. The method of claim 11, wherein step (b3) comprises dissolving the portion of the titanium layer using buffered hydrofluoric acid.

14. A method of forming a media, comprising:
(a) providing a strontium ruthenate layer;
(b) forming a titanium terminated surface on the strontium ruthenate layer;
(c) forming a lead titanate layer on the titanium terminated surface; and
(d) forming a lead zirconate titanate layer on the titanium terminated surface.

15. The method of claim 14, wherein the lead titanate layer is formed on the titanium terminated surface using one of the following:
sputtering;
metal oxide chemical vapor deposition; or
molecular beam epitaxy.

16. A media, comprising:
a strontium ruthenate layer;
a titanium terminated surface on the strontium ruthenate layer; and
a lead zirconate titanate layer on the titanium terminated surface.

17. The media of claim 16, wherein the lead zirconate titanate layer is grown on the titanium terminated surface by step-flow or layer-by-layer growth.

18. The media of claim 16, wherein titanium terminated surface on the strontium ruthenate layer comprises a strontium titanate layer grown on the strontium ruthenate layer.

19. The media of claim 16, wherein the strontium titanate layer has a thickness ranging from 0.4 nm to 4.0 nm.

20. The media of claim 16, wherein the titanium terminated surface on the strontium ruthenate layer comprises titanium oxide on a strontium terminated surface.

21. A media, comprising:
a strontium ruthenate layer;
a titanium terminated surface on the strontium ruthenate layer;
a lead titanate layer on the titanium terminated surface; and
a lead zirconate titanate layer on the titanium terminated surface.

22. The media of claim 21, wherein the lead zirconate titanate layer is grown on the lead titanate layer by step-flow or layer-by-layer growth.

23. A method of forming a media having an atomically smooth surface, comprising:
providing a strontium ruthenate layer having a titanium terminated surface; and
epitaxially growing a lead zirconate titanate layer on the titanium terminated surface, by step-flow or layer-by-layer growth, to thereby form the atomically smooth surface of the media.

24. A method of forming a media having an atomically smooth surface, comprising:
providing a strontium ruthenate layer having a titanium terminated surface;
forming a lead titanate layer on the titanium terminated surface; and
epitaxially growing a lead zirconate titanate layer on the lead titanate layer, by step-flow or layer-by-layer growth, to thereby form the atomically smooth surface of the media.
